(19) United States
(12) Patent Application Publication
(10) Pub. No.: US 2010/0193900 A1
(43) Pub. Date: Aug. 5, 2010

(54) SOI SUBSTRATE AND SEMICONDUCTOR DEVICE USING AN SOI SUBSTRATE

(75) Inventors: Tadahiro Ohmi, Miyagi (JP); Akinobu Teramoto, Miyagi (JP); Sumio Sano, Tokyo (JP); Makoto Yoshimi, Tokyo (JP)

Correspondence Address: FOLEY AND LARDNER LLP;SUITE 500, 3000 K STREET NW, WASHINGTON, DC, 20007, US

(73) Assignee: NATIONAL UNIVERSITY CORPORATION TOHOKU UNIVERSITY, Sendai-shi, Miyagi (JP)

(21) Appl. No.: 12/667,623

(22) PCT Filed: Feb. 25, 2008
(86) PCT No.: PCT/JP2008/055486

§ 371 Date: Jan. 4, 2010

(30) Foreign Application Priority Data
Jul. 13, 2007 (JP) 2007-184896

(51) Int. Cl. H01L 27/12; H01L 21/762

(52) U.S. Cl. 257/507; 438/458; 438/479; 257/E21.568; 257/E27.112

(57) ABSTRACT

A base is formed of a material, such as SiC, having mechanical characteristics higher than those of silicon for forming a semiconductor layer, and the base and the semiconductor layer are bonded through an insulating layer. After bonding, an SOI substrate is formed by mechanically separating the semiconductor layer from the base, and the separated semiconductor layer is reused for forming the subsequent SOI substrate. Thus, a large SOI substrate having a diameter of 400 mm or more, which has been difficult to obtain by conventional methods, can be obtained.

### TECHNICAL FIELD

This invention relates to an SOI substrate, a semiconductor device using the SOI substrate, and a method of manufacturing the same. Herein, an SOI substrate is normally used as an abbreviation of a Silicon On Insulator substrate and the following description will be given of examples using silicon. However, this invention is also usable as a substrate containing a semiconductor other than silicon, such as germanium, gallium, or arsenic (i.e. a Semiconductor On Insulator substrate).

### BACKGROUND ART

Currently, a MOS device using Si (silicon) is widely used as a semiconductor device and it is proposed to perform a reduction in parasitic capacitance or the like, an improvement in threshold value, or the like by forming such a device on a semiconductor layer of an SOI substrate instead of forming it on a Si wafer. As the SOI substrate for use in such an application, since the manufacture is easy, use is often made of an SOI substrate in which a base for support is formed of Si, a SiO₂ insulator layer is provided thereon, and a semiconductor layer made of Si is provided on the insulator layer for element formation. That is, conventionally, the SOI substrate is usually such that the base for support and the semiconductor layer for element formation are both formed of Si.

For example, Patent Document 1 discloses a method of manufacturing an SOI substrate in which an element-side Si substrate and a support-side Si substrate are bonded together through an oxide film. Specifically, Patent Document 1 defines a method of manufacturing an SOI substrate by forming a high-concentration impurity region and a polishing stopper on a surface of an element-side Si substrate, growing a silicon oxide film on the high-concentration impurity region and the polishing stopper, bonding a support-side Si substrate to the silicon oxide film, and then polishing the element-side Si substrate from its other surface to the polishing stopper. According to this manufacturing method, it is possible to obtain SOI substrates with a Si layer thickness of 0.1 μm or less and a variation of 5% or less.

Further, Patent Document 2 discloses a method of manufacturing an SOI substrate in which a silicon nitride film, instead of a silicon oxide film, is deposited on a polished surface of a silicon wafer and another silicon wafer is overlapped and bonded to a surface of the silicon nitride film under heat and pressure. According to this method, since the two silicon wafers are bonded together through the interposed silicon nitride film having a thermal expansion coefficient close to that of silicon, it is possible to prevent the occurrence of bending in the SOI substrate.

On the other hand, in the technical field of this type of semiconductor device, it is required to increase as much as possible the size of substrates for use in the device manufacture, thereby reducing the cost.

Patent Document 1: JP-A-H8-115975

Patent Document 2: JP-A-H5-160087

### DISCLOSURE OF THE INVENTION

### Problem to be Solved by the Invention

If the methods proposed in Patent Documents 1 and 2, etc. are used in terms of such a requirement for the increase in size of SOI substrates, there often arises a situation in which it is not possible to satisfy a recent requirement. For example, if an attempt is made to form a circular substrate with a diameter of 450 mm or a square substrate with a side of 500 mm, there arises a problem that the substrate is easily cracked or warped. That is, the fact is found that if use is made of a substrate in which the support side and the element side are both formed of the same Si, it is not possible to sufficiently satisfy the requirement for the increase in size.

Further, there is a problem that since the heat conduction of a material of a base is poor in a conventional SOI substrate, the heat generated from many devices formed on a semiconductor layer is hard to dissipate through the base so that the operating speed of the devices is reduced.

Further, if Si for use as the above-mentioned base is produced by a floating zone method (FZ method), the Si formed by the FZ method has a purity higher than that of Si formed by a CZ method being a general Si production method, but, because of its low oxygen concentration, is mechanically fragile and tends to be warped. In view of this, it is reportedly difficult to increase the size using Si by the FZ method.

Therefore, it is an object of this invention to provide an SOI substrate that is hard to crack and warp.

It is another object of this invention to provide an SOI substrate excellent in heat conduction.

It is still another object of this invention to provide a large-size SOI substrate using Si produced by the FZ method.

### Means for Solving the Problem

This invention is featured by an SOI substrate comprising a base, an insulator layer provided on one surface of the base, and a semiconductor layer provided on the insulator layer, wherein a material of the base comprises a material that is hard to crack as compared with a material of the semiconductor layer.

Furthermore, this invention is featured in that the material of the base has a bending strength of 200 MPa or more.

Moreover, this invention is featured in that the material of the base has a Young's modulus of 290 GPa or more.

Further, this invention is featured in that the material of the base has a thermal conductivity of 180 W/m·K or more.

It is preferable that the material of the base contains at least one selected from the group consisting of SiC, sapphire, silicon nitride, and aluminum nitride, and especially selected from either SiC or aluminum nitride. The material of the insulator layer may contain at least one of silicon oxide and silicon nitride. The material of the semiconductor layer is, for example, Si and, in this invention, is not limited to Si produced by the CZ method, but may be Si produced by the FZ method.

It is preferable that the substrate has a plane including, on its inside, a circle with a diameter of 400 mm or more, or a square which may have especially angles of four corners of the substrate between 85 to 95 degrees, respectively.

This invention also provides a semiconductor device which has a region wherein at least a part of a semiconductor element is formed in the semiconductor layer of the SOI substrate mentioned above.

### Effect of the Invention

According to this invention, there is obtained an SOI substrate that is hard to crack and warp. Further, according to this invention, there is obtained a substrate excellent in heat conduction.

### BRIEF DESCRIPTION OF THE DRAWINGS

FIG. 1 shows diagrams (a) to (h) for explaining, in order of manufacturing process, a method of manufacturing an SOI substrate according to one embodiment of this invention.

FIG. 2 is a diagram showing one of processes for manufacturing an SOI substrate according to a modification of this invention.

FIG. 3 is a diagram for explaining the process subsequent to FIG. 2.

FIG. 4 is a diagram for explaining the process that is performed after FIG. 3.

FIG. 5 is a diagram for explaining an insulating film on a silicon carbide substrate obtained by the process of FIG. 4.

FIG. 6 is a diagram showing, in comparison, the bending strength, the thermal conductivity, the Young's modulus, and the resistivity in a silicon (Si) material and a material of a base, forming an SOI substrate according to this invention.

### DESCRIPTION OF SYMBOLS

1 silicon substrate
2 SiO₂ film
12 silicon carbide substrate (base)
22 SiO₂ film
23 silicon layer
32 insulating film

### BEST MODE FOR CARRYING OUT THE INVENTION

Hereinbelow, a preferred embodiment to which this invention is applied will be described in detail with reference to the drawings.

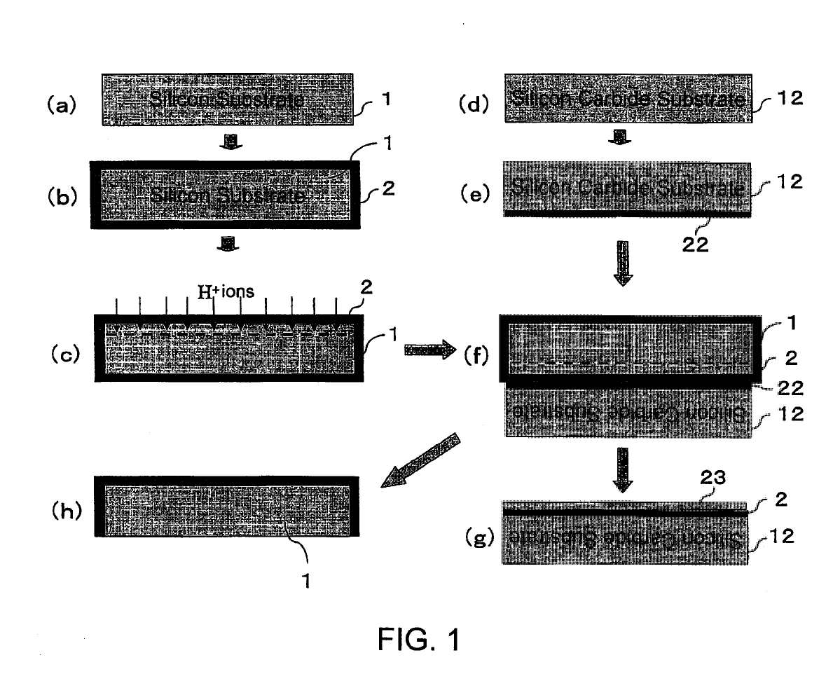

First, referring to FIG. 1, a method of manufacturing an SOI substrate according to this invention will be described. The illustrated example shows a case where an SOI substrate having a rectangular planar shape is manufactured using silicon carbide (SiC) as a material of a base and using silicon (Si) as a semiconductor layer. First, as shown in FIG. 1(a), a silicon substrate 1 is prepared. In this example, a rectangular silicon substrate having a size of 73 cm×92 cm is used as the silicon substrate 1. In this case, the angles of four corners of the rectangular silicon substrate are 85 to 95 degrees. Hereinbelow, a description will be given of the case where a rectangular SOI substrate having a size of 73 cm×92 cm is manufactured, but this invention is suitable for manufacturing an SOI substrate having a plane including, on its inside, a circle with a diameter of 400 mm or more.

Then, as shown in FIG. 1(b), surfaces of the silicon substrate 1 are oxidized to about 100 nm by thermal oxidation, thereby forming a SiO₂ film 2. In this case, the silicon substrate is not limited to one manufactured by the CZ method, but may alternatively be one manufactured by the FZ method.

As illustrated, the SiO₂ film 2 is formed not only at the front and back surfaces of the silicon substrate 1, but also at the side surfaces thereof, i.e. the SiO₂ film 2 is formed over all the surfaces of the silicon substrate 1. Subsequently, as shown in FIG. 1(c), H⁺ ions are implanted to a depth of about 500 nm at one surface of the silicon substrate 1.

On the other hand, as shown in FIG. 1(d), a silicon carbide (SiC) substrate 12 is prepared as a material of a base. Herein, the rectangular silicon carbide substrate 12 having a size of 73 cm×92 cm is prepared and, on one surface thereof, a SiO₂ film 22 is formed to about 100 nm by CVD as shown in FIG. 1(e). Subsequently, the respective substrates shown in FIG. 1(c) and FIG. 1(e) are cleaned by RCA cleaning, thereby removing contaminants on the surfaces.

Then, as shown in FIG. 1(f), the surface, implanted with the H⁺ ions, of the silicon substrate 1 and a surface of the SiO₂ film 22 of the silicon carbide substrate 12 are bonded together. The bonding is carried out by holding in an Ar gas atmosphere at a temperature of 1,100° C. or more for 2 hours. A bonded wafer is heat-treated and then the silicon substrate 1 is mechanically separated from the silicon carbide substrate 12 at a portion, implanted with the H⁺ ions, of the silicon substrate 1. In this case, upon applying a mechanical impact to the silicon substrate 1 implanted with the H⁺ ions, the silicon substrate 1 is ruptured from its portion implanted with the H⁺ ions and, as a result, the silicon substrate 1 can be mechanically separated from the silicon carbide substrate 12 while leaving its portion implanted with the H⁺ ions on the silicon carbide substrate 12.

In the above-mentioned example, the description has been given of the case where H (hydrogen) ions are implanted on the surface side, bonded to the silicon substrate 1, of the silicon carbide substrate 12, but any one kind of H (hydrogen) ions, Ar (argon) ions, He (helium) ions, Kr (krypton) ions, and Ne (neon) ions may be implanted or a plurality of kinds of ions combining those ions may be implanted.

In this manner, as shown in FIG. 1(g), there is obtained an SOI substrate in which the SiO₂ film 22 on the silicon carbide substrate 12 and the SiO₂ film 2 of the silicon substrate 1 are bonded together and, thereon, a silicon layer 23 is formed to a thickness of about 400 nm. This SOI substrate is heat-treated in an Ar atmosphere at a temperature of about 1,100° C. for 2 hours, thereby removing mechanical damage on the surface and, simultaneously, removing the implanted hydrogen ions. Thereafter, CMP is carried out for mirror-finishing the surface. The silicon layer 23 of the SOI substrate thus obtained will be used as one region of semiconductor elements to be formed in subsequent processes.

On the other hand, as shown in FIG. 1(h), the remaining Si substrate 1 separated from the SOI substrate is subjected to surface oxidation and to a treatment in FIG. 1(c) and can be used again for bonding in FIG. 1(f). As described above, according to the SOI substrate manufacturing method of this invention, since the silicon substrate 1 can be repeatedly used, not only the silicon substrate can be effectively used, but also the SOI substrate can be manufactured in a short time as compared with the case where a silicon substrate is separated by etching, polishing, or the like.

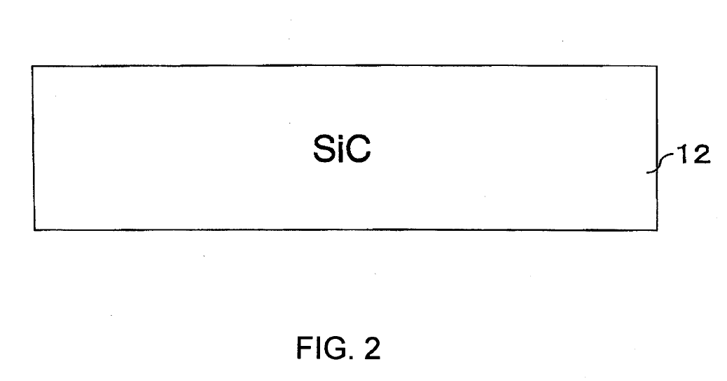

Next, as a modification of the above-mentioned embodiment, a description will be given, referring to FIGS. 2 to 5, of an example in which a silicon oxynitride film (SiON) is used instead of the SiO₂ film 22 on the silicon carbide (SiC) substrate 12 in FIG. 1(e).

First, dilute hydrofluoric acid cleaning is carried out in a pretreatment process and, as a result, SiC dangling bonds on a surface of a silicon carbide substrate 12 are terminated with hydrogen. In FIG. 2, the hydrogen terminating the dangling bonds on the surface of the silicon carbide substrate 12 is removed. More specifically, using Kr for use as a plasma excitation gas in a next oxide film forming process, a surface terminating hydrogen removal treatment and a subsequent oxide film forming treatment are continuously carried out in the same plasma processing chamber. A Kr gas is introduced into the plasma processing chamber at a pressure of about 133 Pa (1 Torr) and a microwave is introduced into the processing chamber to excite the Kr gas, thereby uniformly forming a high-density Kr plasma. The silicon carbide substrate 12 is exposed to the plasma and thus its surface is subjected to low-energy Kr ion irradiation so that the surface terminating hydrogen is removed.

Then, a Kr/O₂ mixed gas is introduced at 400/80 sccm into the same plasma processing chamber and simultaneously a SiH₄ gas is introduced at 0.2 sccm. In this event, the pressure in the processing chamber is maintained at about 133 Pa (1 Torr). The temperature may be set to room temperature. In a high-density excited plasma in which the Kr gas and the O₂ gas are mixed, Kr radicals and O₂ molecules in an intermediate excited state collide with each other so that, a large amount of atomic oxygen O radicals can be efficiently produced.

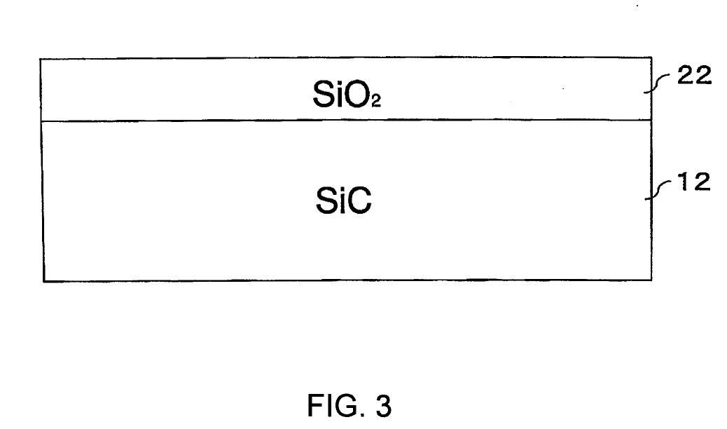

By CVD reaction using the atomic oxygen O radicals and the SiH₄ gas, a silicon oxide film 22 with a thickness of about 100 nm is deposited/formed on the surface of the silicon carbide substrate 12 as shown in FIG. 3. Upon formation of the silicon oxide film 22 with the desired thickness, the introduction of the microwave power is temporarily stopped to finish the plasma excitation and the introduction of the O₂ gas and the SiH₄ gas is stopped.

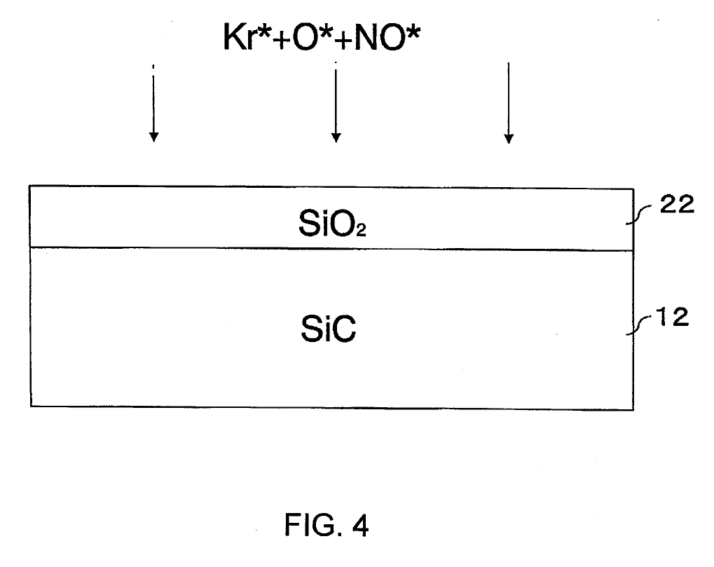

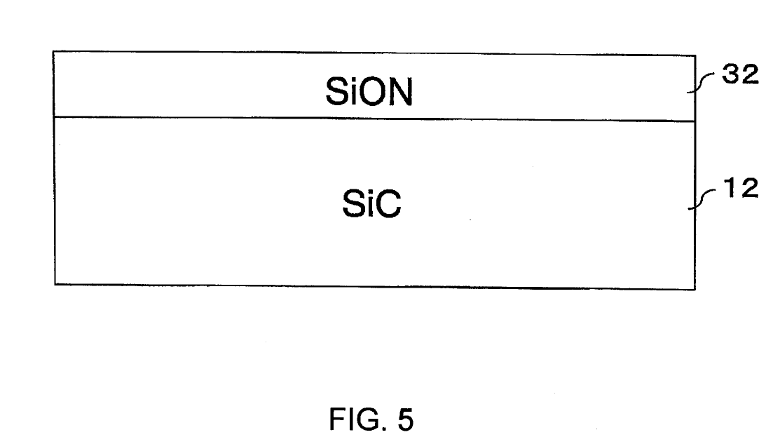

Then, after purging the inside of the processing chamber with Kr, a Kr/O₂/NO mixed gas is introduced at 1000/30/0.001 sccm and, while setting the pressure in the processing chamber to about 133 Pa (1 Torr) and the temperature of the silicon carbide substrate 12 to 600° C., the microwave is supplied again to generate a high-density plasma, thereby changing the properties of the silicon oxide film 22 shown in FIG. 4 to form, as shown in FIG. 5, an insulating film 32 in which at least its surface is a silicon oxynitride film (SiON). This makes it possible to obtain the insulating film 32 improved in interface characteristics. Subsequently, this SiC substrate 12 is bonded to a Si substrate 1 as in FIG. 1(f), thereby forming an SOI substrate. Also in this case, as the Si substrate 1, use can be made of one manufactured by the FZ method.

On the silicon layer 23 serving as a semiconductor layer of the above-mentioned SOI substrate, an insulating film in the form of, for example, an oxide film, a nitride film, or a high-k film is formed as a gate insulating film, a gate electrode is deposited thereon, and by further performing a patterning process, an ion implantation process, a protective film forming process, a wiring layer forming process, a hydrogen sintering process, and so on, it is possible to form a semiconductor integrated circuit including transistors and capacitors. That is, the semiconductor layer is used as one region for semiconductor element formation.

In the above-mentioned embodiment, the description has been given of the example in which SiC is used as the material of the base of the SOI substrate. However, instead of SiC, sapphire, silicon nitride, aluminum nitride, or the like may be used alone or in combination with SiC.

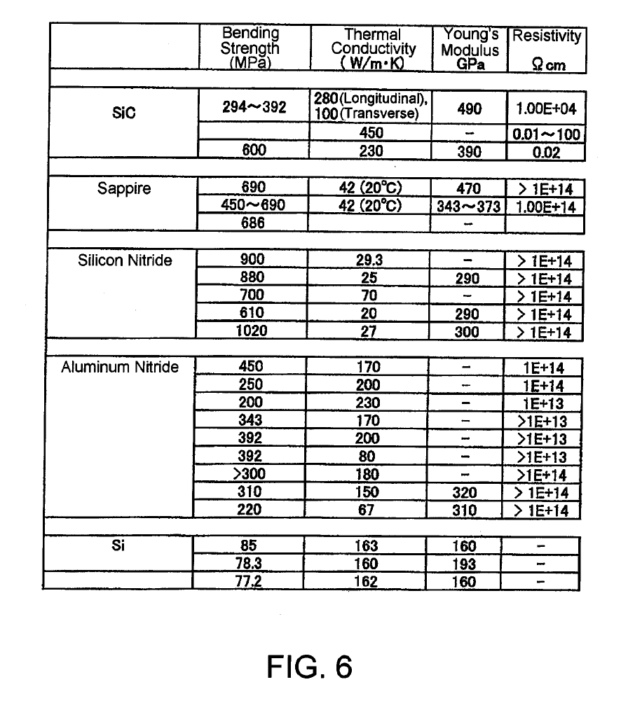

Herein, referring to FIG. 6, the bending strength (MPa), the thermal conductivity (W/m·K), the Young's modulus (GPa), and the resistivity (Ωcm) of silicon carbides (SiC), sapphires, silicon nitrides, and aluminum nitrides are shown in comparison with silicons (Si). Specifically, while the bending strength (MPa) of the silicons is 77.2 to 85, the bending strength (MPa) of the silicon carbides (SiC) is 294 or more. Further, while the Young's modulus (GPa) of the silicons is not more than 200, the Young's modulus (GPa) of the shown silicon carbides (SiC) is 390 or more.

Further, as shown in FIG. 6, the sapphires, the silicon nitrides, and the aluminum nitrides also have a bending strength of 200 MPa or more and a Young's modulus of 290 GPa or more like the silicon carbides. Therefore, the above-mentioned silicon carbides, sapphires, silicon nitrides, and aluminum nitrides each have mechanical properties of being extremely hard to crack and warp as compared with the silicons (Si). Therefore, even if a circular substrate with a diameter of 450 mm or a square SOI substrate with a side of 500 mm is formed, it is not cracked or warped as different from an SOI substrate using silicon as a material of a base.

Further, while the thermal conductivity of the silicons (Si) shown in FIG. 6 is 160 to 163 (W/mK), the shown silicon carbides (SiC) and aluminum nitrides include ones having a thermal conductivity of 180 (W/mK). In this manner, using a material having a thermal conductivity greater than that of silicon (Si) as a base, it is possible to obtain an SOI substrate excellent in thermal conductivity.

### INDUSTRIAL APPLICABILITY

Using an SOI substrate according to this invention, it is possible to form high-speed high-density semiconductor elements or semiconductor devices. Particularly, this invention is suitable for forming an integrated circuit in which semiconductor elements such as CMOSs are integrated in a high density.

1. An SOI substrate comprising a base, an insulator layer provided on one surface of said base, and a semiconductor layer provided on said insulator layer, wherein a material of said base comprises a material that is hard to crack as compared with a material of said semiconductor layer.

2. An SOI substrate according to claim 1, wherein the material of said base has a bending strength of 200 MPa or more.

3. An SOI substrate according to claim 1, wherein the material of said base has a Young's modulus of 290 GPa or more.

4. An SOI substrate according to any claim 1, wherein the material of said base has a thermal conductivity of 180 W/m·K or more.

5. An SOI substrate according to claim 1, wherein the material of said base contains at least one selected from the group consisting of SiC, sapphire, silicon nitride, and aluminum nitride.

6. An SOI substrate according to claim 1, wherein the material of said base is either SiC or aluminum nitride.

7. An SOI substrate according to claim 1, wherein a material of said insulator layer contains at least one of silicon oxide and silicon nitride.

8. An SOI substrate according to claim 1, wherein the material of said semiconductor layer is Si.

9. An SOI substrate according to claim 1, wherein the material of said semiconductor layer is Si produced by a floating zone method (FZ method).

10. An SOI substrate according to claim 1, wherein said substrate has a plane including, on its inside, a circle with a diameter of 400 mm or more.

11. An SOI substrate according to claim 1, wherein a planar shape of said substrate is square.

12. An SOI substrate according to claim 10, wherein angles of four corners of said substrate are 85 to 95 degrees, respectively.

13. A semiconductor device having a region of at least a part of a semiconductor element in said semiconductor layer of the SOI substrate according to claim 1.

14. An SOI substrate manufacturing method comprising the steps of preparing an element forming substrate and a base for supporting said element forming substrate, forming an insulating film on at least one of said element forming substrate and said base, bonding said element forming substrate and said base through said insulating film, and, after bonding, mechanically separating said element forming substrate from said base to produce an SOI substrate, wherein said element forming substrate separated can be reused.

15. An SOI substrate manufacturing method according to claim 14, said method comprising a step of implanting one kind of H (hydrogen) ions, Ar (argon) ions, He (helium) ions, Kr (krypton) ions, and Ne (neon) ions or a plurality of kinds of ions combining them on at least a surface side, to be bonded to said base, among surfaces of said element forming substrate and, after implanting said ions, performing said step of bonding said base and said element forming semiconductor substrate.

16. An SOI substrate manufacturing method according to claim 14, wherein a material of said element forming substrate is silicon, while a material of said base contains at least one selected from the group consisting of silicon carbide, sapphire, silicon nitride, and aluminum nitride.

17. An SOI substrate manufacturing method according to claim 14, wherein said element forming substrate and said base each have an area equal to or greater than an area of a circle with a diameter of 400 mm.

18. An SOI substrate manufacturing method according to claim 14, wherein said insulating film formed on said element forming substrate and said base is a SiO₂ film.

19. An SOI substrate manufacturing method according to claim 14, wherein said insulating film formed on said base is a silicon oxynitride film.

20. An SOI substrate manufacturing method according to claim 19, wherein the step of forming said silicon oxynitride film comprises a step of forming a silicon oxide film on said base and a step of changing a property of said silicon oxide film to form said silicon oxynitride film.
